(19) United States
(12) Patent Application Publication
(10) Pub. No.: US 2025/0318418 A1
(43) Pub. Date: Oct. 9, 2025

(54) HIGH RESOLUTION DPD MASK CLEANING METHODS

(71) Applicant: eMagin Corporation, Hopewell Junction, NY (US)

(72) Inventors: Amalkumar P. GHOSH, Hopewell Junction, NY (US); Howard LIN, Hopewell Junction, NY (US); Fangchao ZHAO, Hopewell Junction, NY (US); Ilyas I. KHAYRULLIN, Hopewell Junction, NY (US)

(21) Appl. No.: 19/169,181

(22) Filed: Apr. 3, 2025

Related U.S. Application Data
(60) Provisional application No. 63/575,180, filed on Apr. 5, 2024.

(51) Int. Cl. H10K 71/16; C23C 14/04

(52) U.S. Cl. CPC H10K 71/166; C23C 14/042

(57) ABSTRACT

A method of cleaning a direct patterning deposition mask is provided where the mask has at least an organic coating material comprising an organic light emitting diode (OLED) material deposited thereon. The method includes the steps of providing a plasma source for providing cleaning plasma for removing the OLED material deposited on the mask, wherein the plasma source utilizes a gas selected from at least one of argon (Ar), nitrogen (N₂), oxygen (O₂), Chlorine (Cl_{2,}) carbon tetrafluoride (CFₓ), sodium hexafluoride (SF₆), and boron trifluoride (BCl₃). The step of providing a plasma source may provide reactive ion etching, inductively coupled plasma, remote plasma, and the like. The step of providing a plasma source may include sequentially providing two or more of the gases.

### CROSS-REFERENCE TO RELATED APPLICATION

This application claims priority to U.S. Provisional Patent Application No. 63/575,180, filed Apr. 5, 2024, entitled High Resolution dPd Mask Cleaning Methods, pending, the entire specification of which is fully incorporated by reference.

### BACKGROUND OF THE INVENTION

The present application is directed to direct patterning deposition (dPd). More particularly, the present invention is directed to shadow mask cleaning in dPd technology in OLED displays.

Shadow-mask-based deposition is a process by which a layer of material is deposited onto the surface of a substrate such that the desired pattern of the layer is defined during the deposition process itself. This is deposition technique is sometimes referred to as “direct patterning.”

Shadow-mask-based deposition has been used for many years in the integrated-circuit (IC) industry to deposit patterns of material on substrates, due, in part, to the fact that it avoids the need for patterning a material layer after it has been deposited. As a result, its use eliminates the need to expose the deposited material to harsh chemicals (e.g., acid-based etchants, caustic photolithography development chemicals, etc.) to pattern it. In addition, shadow-mask-based deposition requires less handling and processing of the substrate, thereby reducing the risk of substrate breakage and increasing fabrication yield. Furthermore, many materials, such as organic materials, cannot be subjected to photolithographic chemicals without damaging them, which makes depositing such materials by shadow mask a necessity.

In a typical shadow-mask deposition process, the desired material is vaporized at a source that is located at a distance from the substrate, with a shadow mask positioned between them. As the vaporized atoms of the material travel toward the substrate, they pass through a set of through-holes in the shadow mask, which is positioned just in front of the substrate surface. The through-holes (i.e., apertures) are arranged in the desired pattern for the material on the substrate. As a result, the shadow mask blocks passage of all vaporized atoms except those that pass through the through-holes, which deposit on the substrate surface in the desired pattern. Shadow-mask-based deposition is analogous to silk-screening techniques used to form patterns (e.g., uniform numbers, etc.) on articles of clothing or stenciling used to develop artwork.

By using direct patterning of OLED with stencil lithography, high-efficiency, high-resolution OLED microdisplays can be fabricated. Color emitter deposition for OLED uses a shadow mask that can have nm scale features. The shadow masks have precision and accuracy to match the underlying transistor of the microdisplay and create color emitters at higher resolution.

A high resolution dPd mask is a critical fixture for high brightness full color micro-OLED manufacturing. During the dPd process, OLED materials are deposited on the dPd mask and through the dPd mask onto a substrate such as a CMOS wafer. Cleaning can maximize the utilization of the dPd mask. Photoresist residuals and dust from the surface of the shadow mask and the depositing holes inside gradually accumulate to block the depositing hole and can cause distortion of the shadow mask such that the organic material cannot be deposited accurately on the substrate to form an organic light emitting layer. This can affect yield and increase manufacturing costs.

### SUMMARY OF THE INVENTION

A method of cleaning a direct patterning deposition mask is provided. The mask has at least an organic coating material comprising an organic light emitting diode (OLED) material deposited thereon. The method includes providing a plasma source for providing cleaning plasma for removing the OLED material deposited on the mask, wherein the plasma source utilizes a gas selected from at least one of argon (Ar), nitrogen (N2), oxygen (O2), Chlorine (Cl2,) carbon tetrafluoride (CFx), sodium hexafluoride (SF6), and boron trifluoride (BCl3). The step of providing a plasma source may provide reactive ion etching. The step of providing a plasma source may provide inductively coupled plasma. The step of providing a plasma source may provide remote plasma. The step of providing a plasma source may include sequentially providing two or more of the gases.

### BRIEF DESCRIPTION OF THE DRAWINGS

FIG. 1 depicts a schematic drawing of a cross-section of the salient features of a direct-patterning deposition system in accordance with the prior art.

FIG. 2 depicts a simplified schematic of an example of a mask cleaning system as used in the present invention.

FIG. 3 is a photograph of Ar/O₂ plasma on BH cleaning in accordance with the present invention.

FIG. 4 is a photograph of Ar/O₂ plasma on Alq3 cleaning in accordance with the present invention.

FIG. 5 is a photograph of Cl₂/O₂ plasma on Alq3 cleaning in accordance with the present invention.

FIG. 6 is a table depicting CL₂/O₂ plasma on Alq3 cleaning showing varying plasma gases, including CL₂ alone, Cl₂ plus O₂, and sequential Cl₂ then O₂ plasma.

FIG. 7 is a table depicting different organic materials with plasma cleaning.

FIG. 8 is a photograph depicting plasma cleaning on a dPd mask.

### DETAILED DESCRIPTION

The present invention provides a cleaning method for the shadow mask 106 to remove photoresist residuals and dust efficiently, thereby improving yield during OLED manufacturing.

Mask cleaning typically has included both wet and dry cleaning methods. Because of the limited thickness of a SiN mask which is typically only 1 um or less thick, wet and other processes require handling which can break the mask. For a dPd mask, dry cleaning such as plasma cleaning is easier to handle and control. The cleaning process can also be integrated into inline deposition, e.g., users can clean the mask in a pre-treatment chamber before organic deposition.

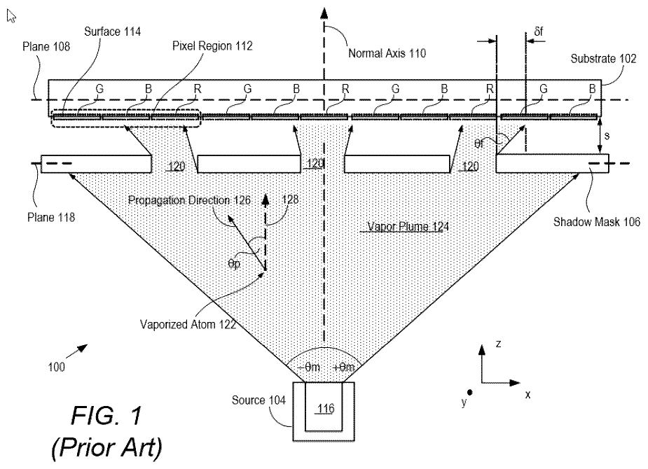

FIG. 1 depicts a schematic drawing of a cross-section of the salient features of a direct-patterning deposition system in accordance with the prior art. System 100 is a conventional evaporation system that deposits a desired pattern of material on a substrate 102 by evaporating the material through a shadow mask 106 positioned in front of the substrate 102. System 100 includes source 104 and the shadow mask 106, which are arranged within a low-pressure vacuum chamber (not shown).

Substrate 102 is provided, suitable for the formation of organic-light-emitting-diode (OLED) displays. Substrate 102 includes surface 114, which defines plane 108 and normal axis 110. Normal axis 110 is orthogonal to plane 108. Surface 114 includes a plurality of deposition sites, G, for receiving material that emits green light, a plurality of deposition sites, B, for receiving material that emits blue light, and a plurality of deposition sites, R, for receiving material that emits red light. The deposition sites are arranged in a plurality of pixel regions 112 such that each pixel region includes one deposition site for the light-emitting material of each color.

Source 104 is a crucible for vaporizing material 116, which is an organic material that emits light at a desired wavelength. The vaporized atoms ejected by source 104 collectively define vapor plume 124.

Shadow mask 106 is a plate of structural material that includes apertures 120. Shadow mask is substantially flat and defines plane 118. The shadow mask 106 is located between source 104 and substrate 102 such that it blocks the passage of all of the vaporized atoms except those that pass through its apertures. The shadow mask and substrate are separated by separation, s, (typically a few tens or hundreds of microns), planes 108 and 118 are substantially parallel, and apertures 120 are aligned with deposition sites.

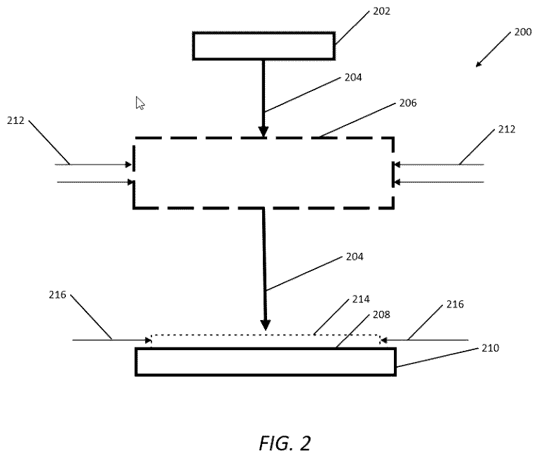

FIG. 2 illustrates a simplified schematic drawing of a dPd mask cleaning system 200 for use in in accordance with the present invention. The mask cleaning system 200 utilizes a remote plasma source 202. Activation gas 204 enters activation zone 206 which is disposed remotely from the surface 208 of the dPd shadow mask 210. OLED materials deposited on the dPd shadow mask 210 must be removed in the plasma cleaning process. Atoms/molecules of activation gas 204 are activated in the activation zone 206 by RF or microwave radiation 212 provided by a radiation source (not shown). After activation, the activation gas 204 enters into excitation zone 214 located near and adjacent to the dPd shadow mask 210. In this zone 214, the activation gas 204 is mixed with process gas 216. The activation gas 204 excites the process gas 216 such that etching plasma is generated in excitation zone 214 and contacts the surface 208 of dPd shadow mask 210 to clean the mask 210.

Plasma cleaning provided by the example of a system 200 or can include different methods, such as reactive ion etching (RIE), inductively coupled plasma (ICP), remote plasma, etc. The cleaning gas can include argon (Ar), nitrogen (N₂), oxygen (O₂), chlorine (Cl₂), carbon tetrafluoride (CFₓ), sulfur hexafluoride (SF₆), boron trifluoride (BCl₃), etc., and the combination of them. Gas and plasma types should be well selected to removing organic materials while leaving the mask without damage. This is because organic materials usually contain organic and metal components. Plasma should be selected based on organic material, such as combination of two or more gas plasma, or a sequential process of one gas plasma followed by another gas plasma. The latter, in other words, means a sequential process of first removing the organic component, then removing the metal component, or vice versa, which can clean the mask.

### EXAMPLE 1

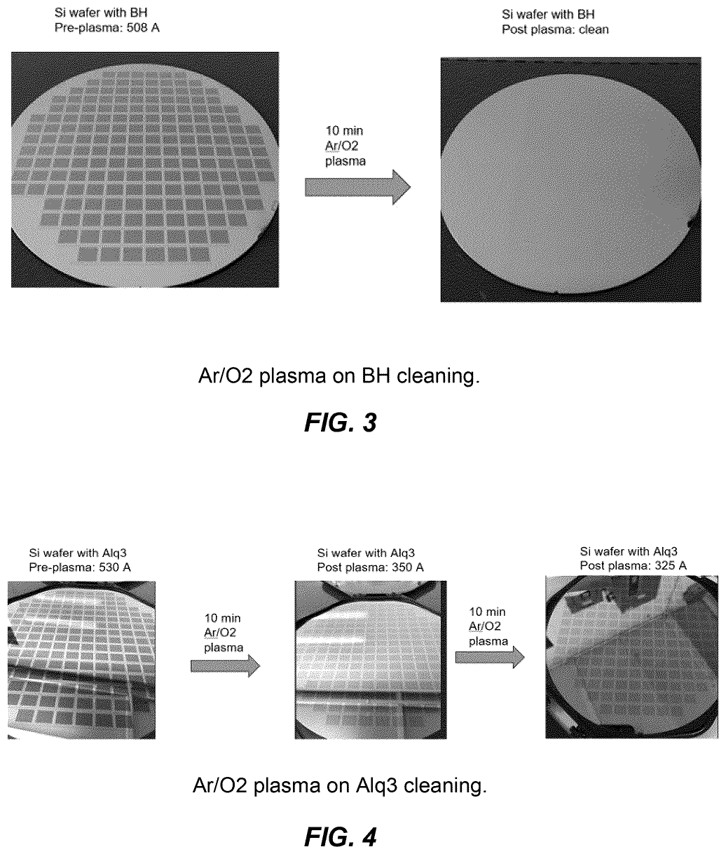

FIG. 3 shows Ar/O₂ plasma can clean BH material. However, for material like Alq3, Ar/O₂ plasma cannot react and remove totally (FIG. 4), which can be ascribed to oxidation of Alq3 in plasma condition.

### EXAMPLE 2

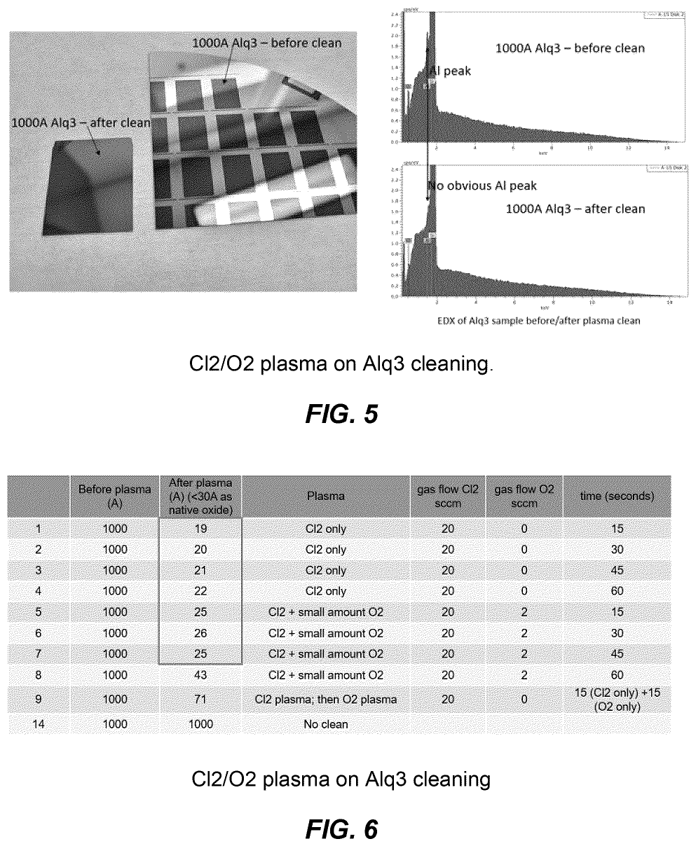

When plasma selected properly like Cl₂/O₂ 2 plasma, the Alq3 can be effectively cleaned away, shown in FIG. 5.

Different recipes of Cl₂/O₂ were provided for plasma cleaning. Most recipes show effective removal of Alq3 to below detection limit of 30A by Ellipsometry method (FIG. 6), which indicate Cl plasma can react with Alq3and take away residue.

### EXAMPLE 3

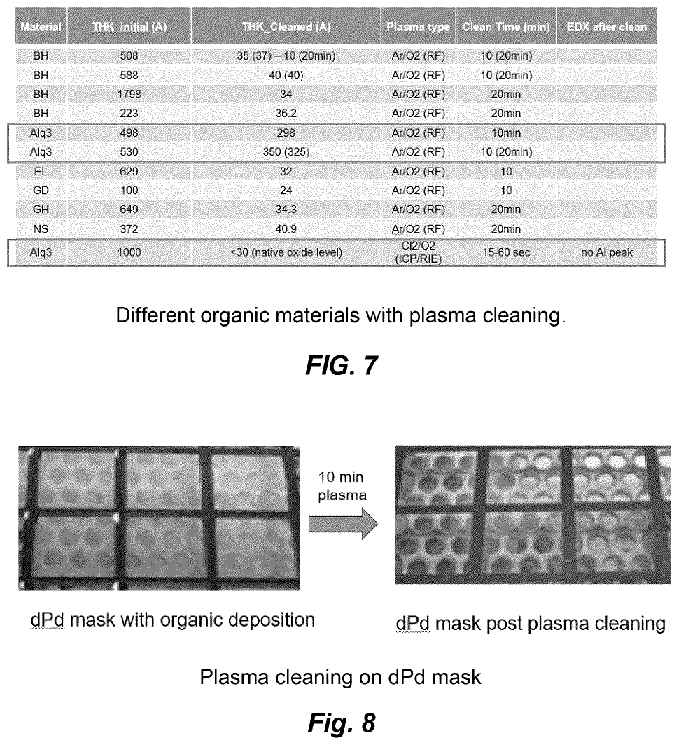

In summary (FIG. 7), we tested different organic materials with plasma cleaning. Ar/O₂ can remove most organic, except for Alq3, which can be removed by Cl₂/O₂ plasma.

### EXAMPLE 4

In plasma cleaning, damage AR was found to dPd mask (FIG. 8), which shows plasma cleaning is a very promising method.

It is to be understood that the disclosure teaches just one example of the illustrative embodiment and that many variations of the invention can easily be devised by those skilled in the art after reading this disclosure and that the scope of the present invention is to be determined by the following claims.

What is claimed is:

1. A method of cleaning a direct patterning deposition mask, the mask having at least an organic coating material comprising an organic light emitting diode (OLED) material deposited thereon, the method comprising:
(a) providing a plasma source for providing cleaning plasma for removing the OLED material deposited on the mask; and
(b) wherein the plasma source utilizes a gas selected from at least one of argon (Ar), nitrogen (N₂), oxygen (O₂), Chlorine (Cl_{2,}) carbon tetrafluoride (CFₓ), sodium hexafluoride (SF₆), and boron trifluoride (BCl₃).

2. The method of cleaning a direct patterning deposition mask of claim 1, wherein the step of providing a plasma source that provides reactive ion etching.

3. The method of cleaning a direct patterning deposition mask of claim 1, wherein the step of providing a plasma source that provides inductively coupled plasma.

4. The method of cleaning a direct patterning deposition mask of claim 1, wherein the step of providing a plasma source that provides remote plasma.

5. The method of cleaning a direct patterning deposition mask of claim 1, wherein the step of providing a plasma source includes sequentially providing two or more of the gases.
